(19) United States
(12) Patent Application Publication
(10) Pub. No.: US 2005/0045952 A1
(43) Pub. Date: Mar. 3, 2005

(54) PFET-BASED ESD PROTECTION STRATEGY FOR IMPROVED EXTERNAL LATCH-UP ROBUSTNESS

(75) Inventors: Kiran V. Chatty, Williston, VT (US); Robert J. Gauthier JR., Hinesburg, VT (US); Mujahid Muhammad, Essex Junction, VT (US); Christopher S. Putnam, Hinesburg, VT (US)

Correspondence Address: CONNOLLY BOVE LODGE & HUTZ LLP, SUITE 800, 1990 M STREET NW, WASHINGTON, DC, 20036-3425, US

(73) Assignee: INTERNATIONAL BUSINESS MACHINES CORPORATION, Armonk, NY (US)

(21) Appl. No.: 10/604,922

(22) Filed: Aug. 27, 2003

(51) Int. Cl. H01L 21/336

(52) U.S. Cl. 257/355; 438/197

(57) ABSTRACT

A method and apparatus for protection against electrostatic discharge (ESD) with improved latch-up robustness featuring a silicide blocked p-type field effect transistor is disclosed. The transistor has a snapback voltage that is less than the breakdown voltage of its gate oxide. The transistor is part of an integrated circuit and coupled to an I/O pad having no n-diffusions connected directly to it. A given integrated circuit may employ one or more the transistors configured in accordance with the invention that are associated with one or more I/O pads within the integrated circuit.

### BACKGROUND OF INVENTION

### FIELD OF THE INVENTION

The present invention relates generally to electrostatic discharge protection for integrated circuits, and more particularly to PFET-based Electrostatic Discharge protection for improved external latch-up robustness.

### BACKGROUND OF THE INVENTION

Advances in modern integrated circuit (IC) technology have enabled MOS devices to be made with ever thinner gate oxides using submicron CMOS technology. Use of thinner gate oxides, however, results in devices that are increasingly susceptible to failure arising from electrical over-stress/electrostatic discharge (EOS/ESD) events.

Such failures can result in the immediate failure of the device, circuit or system.

To reduce the destructiveness of an ESD event, IC designers incorporate protective circuits within their IC layouts to dissipate the energy of a discharge. Such ESD protection circuitry is typically located at or near the input/output (I/O) pad of the IC and must withstand industry standard testing for an IC device to be qualified for commercial applications. Several models exist to simulate ESD events in order to test the effectiveness of ESD protection circuitry. The models are generally classified into one of three forms: the human body model (HBM), the machine model (MM), and the charged device model (CDM). The HBM simulates the action of a human body discharging accumulated static charge through a device to ground. The model employs a series RC network consisting of a 100-pF capacitor and a 1500-Ohm resistor. The MM simulates a machine discharging accumulated charge through a device to ground. The model utilizes a series RC network of a 200-pF capacitor and nominal series resistance of less than one ohm. The CDM simulates the charging/discharging that is found to occur in production equipment and processes. CDM ESD events occur as a result of metal-to-metal contact that can arise during manufacturing, such as a device sliding down a tube and hitting a metal surface. CDM testing consists of charging a package to a specified voltage, then discharging this voltage through relevant package leads.

Another phenomenon that can occur in CMOS structures is latch-up. Latch-up is the appearance of a low impedance path between power supply rails that results from the triggering of parasitic devices within the CMOS structure. It is an inherent byproduct of modern CMOS design and arises due to the close proximity of n-channel and p-channel devices within the CMOS wafer. Latch-up is a problem inherent to bulk starting-wafer CMOS.

Semiconductor companies traditionally use one of two types of ESD protection strategies in the design of their ICs to qualify under one or more of the above test models: a diode-based strategy or an NMOS-based strategy. FIG. 1 illustrates a conventional ESD protection circuit 100 employing a diode-based strategy. The ESD circuit 100 consists of resistor R and diodes D1 and D2 connected between input pad 101 and input stage 130. The resistor R is connected in series between terminal 102 of the input pad 101 and terminal 103, with one end of resistor R being connected to terminal 102 of input pad 101, and the other end of resistor R being connected to terminal 103, which is connected to the gates 145, 150 of the MOS devices P1, N1 of input stage 130.

The ESD protection circuit 100 provides two discharge paths: one from the terminal 103 to Vss through diode D1 and another discharge path from the terminal 103 to Vdd through diode D2. The first diode D1 has its anode 123 connected to the Vss bus and its cathode 122 connected to terminal 103. The second diode D2 has its anode 121 also connected to the terminal 103, while its cathode 120 is connected to the Vdd bus. While the circuit 100 provides some ESD protection, including two discharge paths, ESD damage to the PMOS device P1 may nevertheless occur under certain conditions. For example, when the Vdd bus is floating, a positive HBM ESD pulse with respect to the Vss bus occurring at input pad 101, can damage the PMOS device P1.

FIG. 2 illustrates a conventional ESD protection circuit 200 employing an NMOS-based strategy. The ESD circuit consists of NMOS device N2 connected between terminal 202 of input pad 201 and the Vss bus, which is grounded. The drain 230 of NMOS device N2 is connected to terminal 202 of input pad 201. The gate 231 and source 232 of NMOS device N2 are connected to the grounded Vss bus. The resistor R is connected between terminal 202 and terminal 203, which is connected to the gates 245, 250 of MOS devices P1 and N1 of input stage 230.

A PMOS device P2 is connected between terminal 202 of input pad 201 and the Vdd bus. The drain 222 of PMOS device P2 is connected to terminal 202 of input pad 201. The gate 221 and source 220 of PMOS device P2 are connected to the Vdd bus. Thus, gates 231, 221 of each device N2, P2 are shorted to their respective sources 232 and 220, while drains 230, 222 are connected to terminal 202 of input pad 201.

The ESD protection circuit 200 provides two discharge paths: one path from input pad 201 to the Vdd bus, and a second path from input pad 201 to the Vss bus. In ESD protection circuits using CMOS devices, however, the CMOS devices must be surrounded with double guard rings to overcome latch-up, which inhibits the CMOS devices. The NMOS N2 and PMOS P2 devices in the ESD protection circuit 200 are generally located at different distances from the input pad 201. Therefore, the NMOS N2 and PMOS P2 are each surrounded by their own double guard rings. This results in even a larger total layout area. Thus, conventional ESD protection circuits employed to pass the HBM, MM or CDM tests must compromise on their effectiveness to resist latch-up unless they incur significant process complexity and cost.

A typical latch-up condition can be seen by referring to FIGS. 3A and 3B. If a small stray current (Is) flows through the p-substrate due to, say, an ESD event at the input pad, a voltage drop will form through the substrate by virtue of the substrate resistance Rs. If the potential within the p-substrate reaches a diode built-in voltage level, typically 0.7 Volts, the emitter-base junction of Q2 will forward-bias and turn Q2 ON. As Q2 turns ON, current is drawn from the n-well, which in turn causes a voltage drop to form across the n-well resistance Rw. If the potential within the n-well reaches a diode built-in voltage level (below Vdd), again typically 0.7 Volts, the emitter-base junction of Q1 will forward-bias and turn Q1 ON. As Q1 turns ON, Is increases, which causes Q2 to turn ON “harder,” which in turn causes Q1 to turn ON harder, and so on. This positive feedback condition ensures that both Q1 and Q2 remain ON in the forward/active mode; and the current flowing through each transistor ensures that the other remains ON. Thus latched, the circuit is no longer dependent on the triggering source and a continual low-impedance/short-circuit path exists between Vdd and ground/Vss.

Latch-up testing of ICs is performed in accordance with EIA/JEDEC Standard EIA/JESD78, which requires, in part, injection of current at the I/O of the Device Under Test (DUT) in both positive and negative modes. Because the ESD device is the first circuit connected to the I/O pad, it is the first device to turn ON and is the lowest impedance device connected to the I/O pad when latch-up testing is conducted. During testing, when positive current is injected, any p-type diffusion connected to the pad will forward-bias. When negative current is injected, the n-type diffusions will forward-bias.

On a p-starting wafer, any p-type device connected to the pad will usually inject holes into the p-substrate. These majority carriers can be controlled by moderating the resistance of the local substrate contacts. Thus, the positive mode injection test can be handled locally around the ESD device by use of substrate rings (guard rings) to control substrate resistance. In negative mode testing, however, minority carriers (electrons) are injected into the p-substrate. These minority carriers are collected by n-well guard rings but not all are collected without adding exceptional process complexity and costs. Thus, some electrons escape and the higher the doping of the p-type substrate, the shorter distance the electrons will diffuse. On a p-substrate, however, the escaped electrons can diffuse a distance of up to 600 microns and thereby serve as a latch-up trigger in other circuitry on the substrate.

In a product where I/O terminals are surrounded by standard logic, gate array circuits or custom logic, any diffusions (n+ or p+) connected to the I/O pads during a latch-up current injection can forward-bias and inject enough current to contribute to the latch-up of these surrounding circuits. A condition of positive mode latch-up (injection of holes) can be resolved by providing local substrate contacts that clamp substrate potentials to less than 0.5 Volts to prevent forward-biasing any n-diffusions. In negative mode latch-up, however, any n-diffusion that is connected to the I/O pad will forward-bias and inject n-type carriers into the p-material and be available to trigger latch-up as described above. Because conventional ESD protection schemes employ n-diffusions, they inherently contribute to a latch-up prone state that can only be cured by added process complexity and cost. For instance, when an NFET based strategy is used, 50 microns on each side of each I/O on the wafer will be lost because of large guard ring structures for the external latch-up protection. This results in an increased dedication of chip area of approximately 60% for allocation to the additional protective structures.

What is needed, therefore, is an ESD protection circuit that can provide adequate ESD protection to meet the HBM, MM or CDM tests that can concurrently provide superior latch-up robustness.

### SUMMARY OF INVENTION

The present invention is directed to a method and apparatus for protection against electrostatic discharge (ESD) with improved latch-up robustness. The disclosure features a silicide blocked p-type field effect transistor that has a snapback voltage that is less than the breakdown voltage of the gate oxide of the transistor. The transistor is part of an integrated circuit and is coupled to an I/O pad having no n-diffusions connected directly to it. The integrated circuit may have one or more I/O cells having one or more I/O pads, with one or more of the I/O pads having latch-up robust ESD protection in accordance with the present disclosure. The low snapback voltage is useful to drive the associated parasitic bipolar junction transistor to forward/active mode in order to shunt destructive ESD current and thus avoid latch-up. The low snapback voltage enables use of p-type only devices in an ESD protection circuit. By using only p-type devices in the ESD protection circuit, I/O pads do not have any connected n-diffusions. Thus, n-type guard rings are not necessary for latch-up prevention, which results in a significant savings of area on the IC. A given integrated circuit may employ one or more the transistors configured in accordance with the disclosure.

### BRIEF DESCRIPTION OF DRAWINGS

FIG. 1 illustrates a conventional ESD protection circuit employing a diode-based strategy.

FIG. 2 illustrates a conventional ESD protection circuit employing an NMOS-based strategy.

FIG. 3A illustrates a cross-section of a CMOS device with parasitic bipolar junction transistors Q1 and Q2.

FIG. 3B illustrates a schematic diagram of the circuit formed by the parasitic bipolar junction transistors depicted in FIG. 3A.

FIG. 4 is a schematic diagram of a bidirectional IC in accordance with the present invention.

FIG. 5 is a schematic diagram of a bidirectional IC in accordance with the present invention.

FIG. 6 is a schematic diagram of a bidirectional IC in accordance with the present invention.

FIG. 7 is a cross-section of a p-type field effect transistor formed in accordance with the present invention.

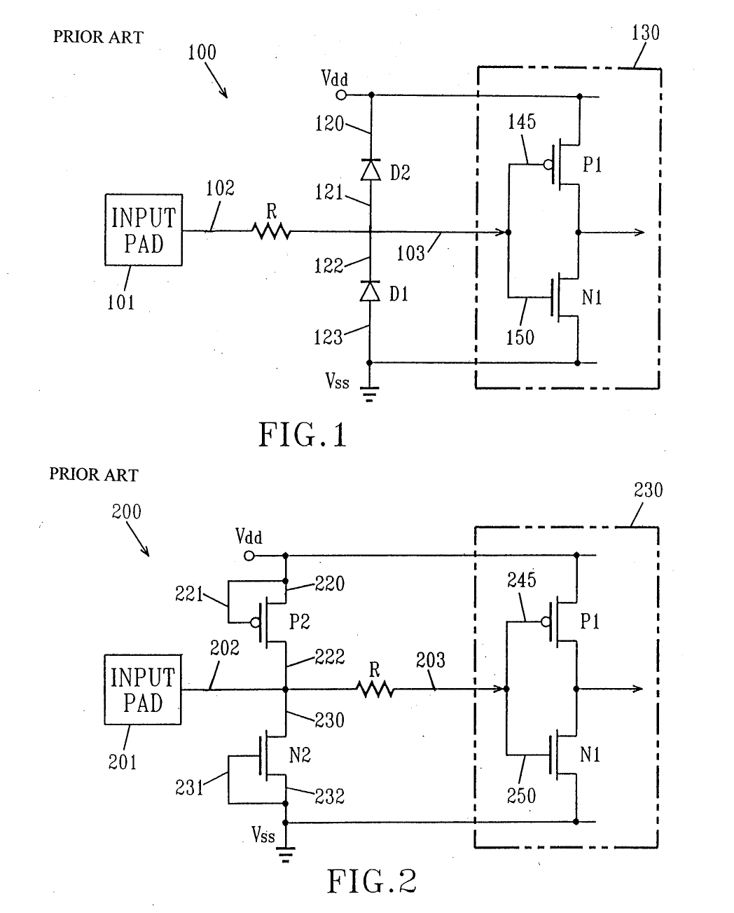

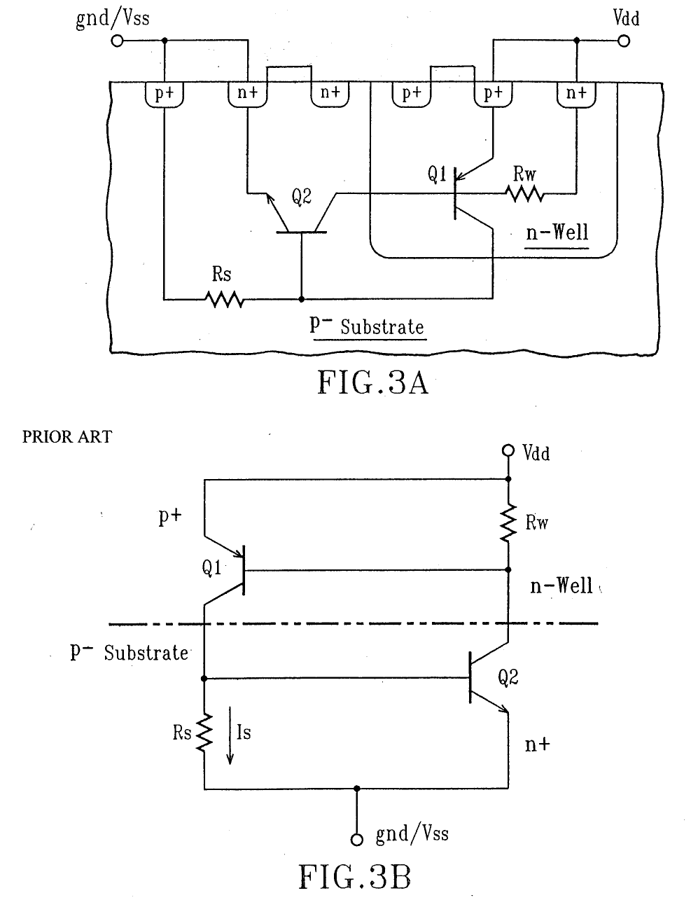

### DETAILED DESCRIPTION

New circuit configurations described here use area efficient p-type field effect transistors to conduct current generated during an ESD event. Each disclosed p-type field effect transistor is formed within an n-well contained within a p-substrate and is silicide blocked. Silicide blocking is used to increase the level of parasitic resistance in order to improve current spread across the width of the device. Transistor connection to the I/O pad is direct so that no n-diffusions are directly connected to the I/O pad. Note that the integrated circuit within which the transistor is used may have one or more I/O cells having one or more I/O pads, with one or more of the I/O pads having latch-up robust ESD protection in accordance with the present disclosure. Note that the figures and associated description below describe connection to an input stage and pre-drive circuitry. Such connections are for illustrative purposes only in order to provide a context for the invention and should not be construed as limiting or necessary to the invention.

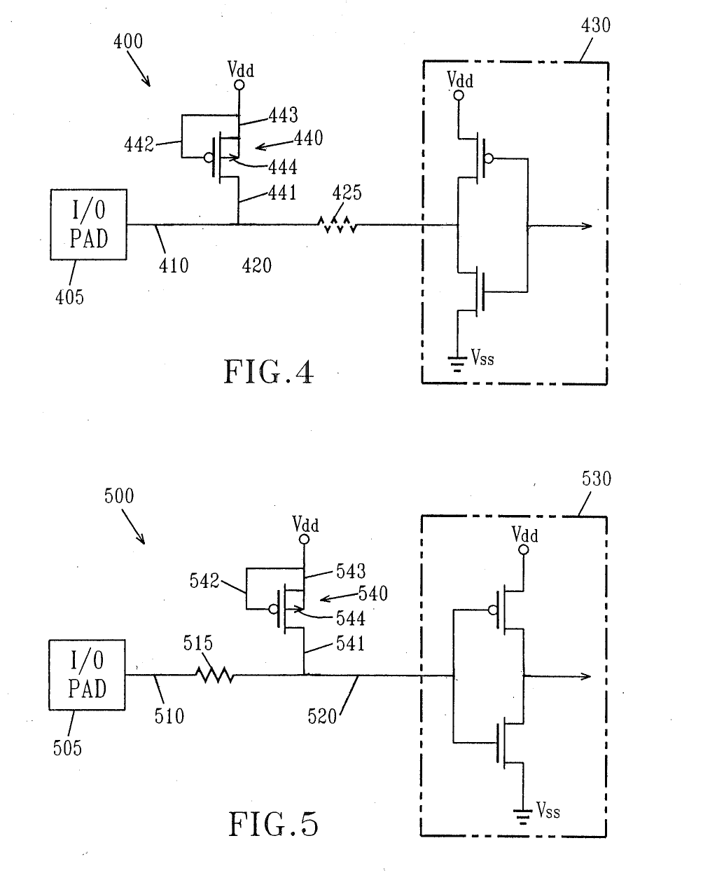

FIG. 4 is a schematic diagram of bidirectional IC 400 featuring one embodiment of the inventive ESD protection circuit. Coupled between I/O pad 405 and input stage 430 is p-type field effect transistor 440. Optionally, a p-type impedance matching resistor 425 may be provided between p-type field effect transistor 440 and input stage 430.

The ESD protection circuit depicted in FIG. 4 provides a discharge path to the Vdd rail through p-type field effect transistor 440, which is coupled between node 420 and Vdd. P-type field effect transistor 440 has a drain 441, gate 442, source 443, and body terminal 444. The drain 441 of p-type field effect transistor 440 is connected to I/O pad 405 and node 420. Gate 442 and body terminal 444 of p-type field effect transistor 440 are connected to source 443, which is connected to Vdd. The embodiment of the inventive ESD protection circuit illustrated in FIG. 4 is particularly suitable to HBM and MM testing and like discharge events, but is not limited to such applications.

Optional p-type impedance matching resistor 425, if provided, has two ends that yield electrical connection; one end that is connected to node 420 and p-type field effect transistor 440, and another end that is connected to input stage 430. P-type resistor 425 may be a diffusion resistor or a polysilicon resistor or formed of p-type material suitable to provide a voltage drop between node 420 and input stage 430. Resistor 425 should be p-type so as not to provide an n-diffusion connection to I/O pad 405.

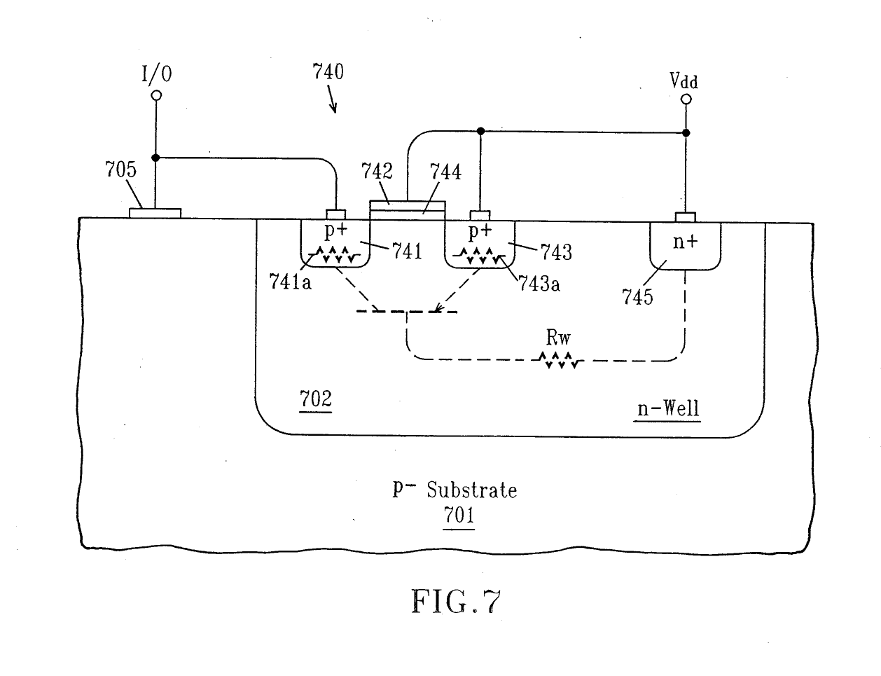

It can be seen from the schematic diagram of FIG. 4 that during normal operating conditions p-type field effect transistor 440 is turned OFF. During an ESD event, however, the parasitic bipolar transistor formed by p-type field effect transistor 440 turns ON to a negative ESD voltage exceeding the bipolar turn-on voltage of the parasitic pnp formed beneath the PMOS. This effectively shunts the destructive ESD current to Vdd for discharge to ground through chip capacitance and/or ESD power clamping circuitry. During a positive ESD voltage, the current flows through the p+/n-well diode formed from the p-type field effect transistor drain to the n-well contact, carriers are collected by a p-type guard ring (not shown). A detailed description of the parasitic bipolar transistor is provided in association with the description of FIG. 7.

FIG. 5 illustrates a schematic diagram of bidirectional IC 500 featuring another embodiment of the inventive ESD protection circuit. Coupled between I/O pad 505 and input stage 530 are p-type resistor 515 and p-type field effect transistor 540. Having two ends that yield electrical connection, one end of p-type resistor 515 is connected to the terminal 510 of I/O pad 505, and another end of p-type resistor 515 is connected to node 520, which is connected to p-type field effect transistor 540 and input stage 530. P-type resistor 515 may be a diffusion resistor or a polysilicon resistor or formed of p-type material suitable to provide voltage drop between I/O pad 505 and node 520.

The ESD protection circuit depicted in FIG. 5 provides a discharge path to the Vdd rail through p-type field effect transistor 540, which is coupled between node 520 and Vdd. P-type field effect transistor 540 has a drain 541, gate 542, source 543, and body terminal 544. The drain 541 of p-type field effect transistor 540 is connected to node 520 and p-type resistor 515. Gate 542 and body terminal 544 of p-type field effect transistor 540 are connected to source 543, which is connected to Vdd. The embodiment of the inventive ESD protection circuit illustrated in FIG. 5 is particularly suitable to CDM testing and like discharge events, but is not limited to such applications.

It can be seen from the schematic diagram of FIG. 5 that during normal operating conditions p-type field effect transistor 540 is turned OFF. During an ESD event, however, the parasitic bipolar transistor formed by p-type field effect transistor 540 turns ON to a negative ESD voltage exceeding the transistor's parasitic pnp turn-on voltage. This effectively shunts the destructive ESD current to Vdd for discharge to ground through chip capacitance and/or ESD power clamping circuitry. During a positive ESD voltage, the current flows through the p+/n-well diode formed from the p-type field effect transistor drain to the n-well contact, carriers are collected by a p-type guard ring (not shown). A detailed description of the parasitic bipolar transistor is provided in association with the description of FIG. 7.

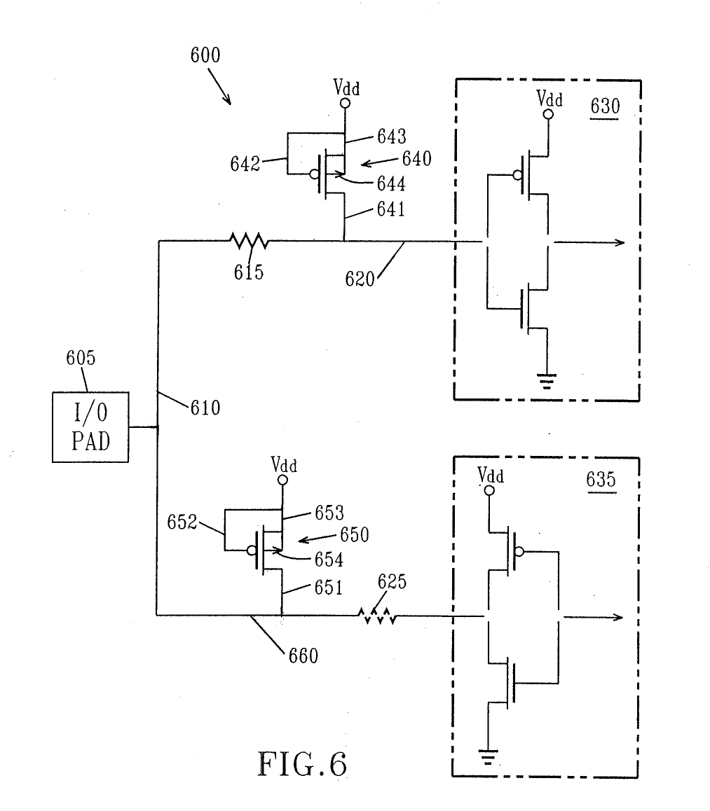

FIG. 6 illustrates a schematic diagram of bidirectional IC 600 featuring another embodiment of the inventive ESD protection circuit. Coupled between I/O pad 605 and input stage 630 is p-type resistor 615 and p-type field effect transistor 640; coupled between I/O pad 605 and pre-drive inverter 635 is p-type field effect transistor 650. Optionally, a p-type impedance matching resistor 625 may be provided between p-type field effect transistor 650 and pre-drive inverter 635.

Having two ends that yield electrical connection, one end of p-type resistor 615 is connected to terminal 610 of I/O pad 605, and another end of p-type resistor 615 is connected to node 620, which is connected to p-type field effect transistor 640 and input stage 630. P-type resistor 615 may be a diffusion resistor or a polysilicon resistor or formed of p-type material suitable to provide voltage drop between I/O pad 605 and node 620.

The ESD protection circuit depicted in FIG. 6 provides a first discharge path to the Vdd rail through p-type field effect transistor 640, which is coupled between node 620 and Vdd. P-type field effect transistor 640 has a drain 641, gate 642, source 643, and body terminal 644. The drain 641 of p-type field effect transistor 640 is connected to node 620 and p-type resistor 615. Gate 642 and body contact 644 of p-type field effect transistor 640 are connected to source 643, which is connected to Vdd. This portion of the inventive ESD protection circuit illustrated in FIG. 6 is particularly suitable to CDM testing and like discharge events, but is not limited to such applications.

The ESD protection circuit depicted in FIG. 6 provides a second discharge path to the Vdd rail through p-type field effect transistor 650, which is coupled between node 660 and Vdd. P-type field effect transistor 650 has a drain 651, gate 652, source 653, and body terminal 654. The drain 651 of p-type field effect transistor 650 is connected to I/O pad 605 and node 660. Gate 652 and body contact 654 of p-type field effect transistor 650 are connected to source 653, which is connected to Vdd. This portion of the inventive ESD protection circuit illustrated in FIG. 6 is particularly suitable to HBM and MM testing and like discharge events, but is not limited to such applications.

Optional p-type impedance matching resistor 625, if provided, has one end that is connected to node 660 and p-type field effect transistor 650, and another end that is connected to pre-drive inverter 635. P-type resistor 625 may be a diffusion resistor or a polysilicon resistor or formed of p-type material suitable to provide voltage drop between node 660 and pre-drive inverter 635. Resistor 625 should be p-type so as not to provide an n-diffusion connection to I/O pad 605.

It can be seen from the schematic diagram of FIG. 6 that during normal operating conditions p-type field effect transistors 640 and 650 are turned OFF. During an ESD event, however, the parasitic bipolar transistor formed by each p-type field effect transistor 640 and 650 turns ON in response to a negative ESD voltage when that voltage exceeds the transistors' parasitic bipolar turn-on voltage; current then divides between the two paths stemming from the I/O pad. This construction effectively shunts the destructive ESD current to Vdd for discharge to ground through chip capacitance and/or ESD power clamping circuitry. Note that the local gate voltage at node 620 is reduced in magnitude from the voltage at I/O pad 605 due to the IR drop across p-type resistor 615. During a positive ESD voltage, carriers are collected by a p-type guard ring (not shown). A detailed description of the parasitic bipolar transistor is provided in association with the description of FIG. 7.

FIG. 7 illustrates a cross-section of a p-type field effect transistor formed in accordance with the present invention (silicide blocking not shown). P-type field effect transistor 740 is formed of a gate 742 atop a gate dielectric 744 upon an n-well 702 within a p-substrate 701. The gate 742 is positioned between drain p+ diffusion 741 and source p+ diffusion 743 within n-well 702. Spaced apart from p+ diffusions 741 and 743 is body contact n+ diffusion 745, also formed within n-well 702. I/O pad 705 is directly connected to drain P+ diffusion 741. Gate 742, source p+ diffusion 743, and body contact n+ diffusion 745 are all tied to Vdd.

By virtue of the formation of the p-type field effect transistor, a parasitic pnp bipolar junction transistor (BJT) is available. The junction between drain p+ diffusion 741 and the n-well 702 form the collector of the parasitic pnp BJT, whereas the junction between the source p+ diffusion 743 and n-well 702 form the emitter of the parasitic pnp BJT. The base of the parasitic pnp BJT is coupled to Vdd at the body contact n+ diffusion 745 through the n-well 702 internal resistance Rw. Drain resistance 741a and source resistance 743a are facilitated by silicide blocking to increase the level of parasitic resistance in order to improve current spread across the width of the device.

During a negative ESD voltage or negative mode ESD testing, the voltage at drain p+ diffusion 741 decreases relative to the n-well potential; the drain p+ diffusion 741 and n-well 702 junction reverse-biases. As the magnitude of the voltage increases, the electric field across the depletion region in the drain p+ diffusion 741 and n-well 702 junction becomes high enough for avalanche multiplication of charge carriers to occur, and the junction goes into avalanche breakdown with the generation of electron-hole pairs. During avalanche multiplication on the drain side of the device, electrons are injected into n-well 702, thus driving the n-well potential below Vdd. Eventually, the source p+ diffusion 743 and n-well 702 junction will forward-bias and the parasitic pnp BJT will then be in forward-active mode and conducting. Note that during negative mode ESD testing Vdd is typically tied to ground.

The voltage at which the source p+ diffusion 743 and n-well 702 junction enters forward-bias, and thereby turning ON the parasitic pnp BJT, is referred to as the snapback voltage. The snapback voltage should be less than the breakdown voltage of the gate dielectric 744. Lower snapback voltage can be achieved though reduction in gate length and higher doping concentration of the halo implant. The halo or “pocket” implant improves the short channel behavior of CMOS devices. The halo implant uses the same implant type as the original well dopant (for example, n-type dopant for the n-well of a PMOS device) and together with the well implant, establishes the threshold voltage of the transistor. For example, a gate oxide of 22 Angstroms in a 0.13 micron technology generation has a breakdown voltage of approximately 8 Volts (for a pulse-width of approximately 100-200 nanoseconds). A snapback voltage of approximately 5 Volts is achievable utilizing a gate length of less than approximately 100 nm and halo implant dopings of approximately 2 E 18. This technique to reduce snapback voltage enables p-type field effect transistors to be used as ESD protection devices. Thus, occurrence of the n-diffusions associated with n-type devices is eliminated, which in turn eliminates the need for large guard ring structures or dead zones necessary to protect from external latch-up arising from the n-diffusions.

Numerous characteristics and advantages have been set forth in the foregoing description, together with details of structure and function. The novel features are pointed out in the appended claims. The disclosure, however, is illustrative only and changes may be made in detail within the principle of the invention to the full extent indicated by the broad general meaning of the terms in which the appended claims are expressed.

1. A method of forming a semiconductor device with increased latch-up robustness, the method comprising:
providing a p-type semiconductor substrate;
locating within said substrate an I/O pad having no direct connection to n-diffusions;
forming within said substrate an n-well;
forming within said n-well a silicide blocked p-type field effect transistor having a snapback voltage that is less than the breakdown voltage of the gate oxide of said transistor.

2. An ESD device comprising:
a silicide blocked p-type field effect transistor having a source, drain, gate, and gate oxide, said transistor further having a snapback voltage that is less than the breakdown voltage of said gate oxide and wherein said transistor is coupled to an I/O pad having no n-diffusions connected directly to it.

3. The ESD device of claim 2 wherein said source is coupled to a voltage and said gate is coupled to said source and said drain is coupled said I/O pad.

4. The ESD device of claim 2 further having a body terminal.

5. The ESD device of claim 4 wherein said body terminal is coupled to said source.

6. The ESD device of claim 2 wherein said snapback voltage is at most 5 volts.

7. The ESD device of claim 2 wherein a p-type resistor is coupled to said transistor and coupled said I/O pad.

8. The ESD device of claim 7 wherein said resistor is formed of p-type polysilicon.

9. The ESD device of claim 7 wherein said resistor is a diffusion resistor.

10. The ESD device of claim 7 wherein said p-type resistor is located between said transistor and said I/O pad so that a first voltage appearing at said I/O pad is of a different magnitude than a second voltage appearing at said transistor, said first and second voltages differing by a value proportional to the resistance of said p-type resistor.

11. A latch-up robust integrated circuit comprising:
one or more I/O cells each having one or more I/O pads with no n-diffusions directly connected and wherein each of said one or more I/O pads is coupled to an associated and distinct one or more suicide blocked p-type field effect transistors having a source, drain, gate, and gate oxide, said transistor further having a snapback voltage that is less than the breakdown voltage of said gate oxide.

12. The latch-up robust integrated circuit of claim 11 wherein each of said one or more I/O pads is coupled said drain of said associated and distinct one or more transistors and said source of said transistors is coupled to a voltage and said gate is coupled to said source.

13. The latch-up robust integrated circuit of claim 12 wherein each of said transistors has a body terminal.

14. The latch-up robust integrated circuit of claim 13 wherein said body terminal of each of said transistors is coupled to said source.

15. The latch-up robust integrated circuit of claim 11 wherein said snapback voltage of each of said transistors is at most 5 volts.

16. The latch-up robust integrated circuit of claim 11 wherein one or more p-type resistors is coupled to one or more of each of said one or more I/O pads.

17. The latch-up robust integrated circuit of claim 16 wherein each of said one or more p-type resistors is formed of p-type polysilicon.

18. The latch-up robust integrated circuit of claim 16 wherein each of said one or more p-type resistors is a diffusion resistor.

19. The latch-up robust integrated circuit of claim 16 wherein at least one of said one or more p-type resistors is located between the pad and associated transistor of each of said I/O pads so that a first voltage appearing at any of said I/O pads is of a different magnitude than a second voltage appearing at the associated transistor, said first and second voltages differing by a value proportional to the resistance of the p-type resistor.
